(19) United States
(12) Patent Application Publication
(10) Pub. No.: US 2021/0320224 A1
(43) Pub. Date: Oct. 14, 2021

(54) LIGHT-EMITTING DEVICE

(71) Applicant: Sony Corporation, Tokyo (JP)

(72) Inventors: Kunihiko TASAI, Tokyo (JP); Hidekazu KAWANISHI, Tokyo (JP); Katsunori YANASHIMA, Tokyo (JP)

(21) Appl. No.: 17/268,375

(22) PCT Filed: Aug. 2, 2019
(86) PCT No.: PCT/JP2019/030492

§ 371 Date: Feb. 12, 2021

(30) Foreign Application Priority Data
Aug. 16, 2018 (JP) 2018-153056

(51) Int. Cl. H01L 33/32; H01S 5/343; H01L 33/06

(52) U.S. Cl. CPC H01L 33/32; H01L 33/06; H01S 5/34333

(57) ABSTRACT

A light-emitting device according to one embodiment of the present disclosure includes: a substrate; a first quantum well layer including Alₓ₂Inₓ₁Ga₍₁₋ₓ₁₋ₓ₂₎N (0<x1<1, 0≤x2<1) and including a light-emitting region; a barrier layer provided between the substrate and the first quantum well layer; and a second quantum well layer including Al_{y2}In_{y1}Ga_{(1-y1-y2)}N (0<y1<1, 0≤y2<1) and having a thickness of less than 4.0 monolayers and provided between the substrate and the barrier layer, at a position 8 nm or more and less than 50 nm away from the first quantum well layer.

### TECHNICAL FIELD

The present disclosure relates to a light-emitting device including, for example, a gallium nitride (GaN)-based material.

### BACKGROUND ART

Light-emitting devices including gallium nitride (GaN)-based materials have been actively developed. Examples of light-emitting devices include a semiconductor laser (LD: Laser Diode), a light-emitting diode (LED: Light Emitting Diode), and the like. In a light-emitting device that emits light with a wavelength of a visible region, a light-emitting layer is formed using GaInN as a GaN-based material. An emission wavelength of GaInN increases with an increase in composition of In. On the other hand, emission efficiency tends to decrease as the composition of In increases.

In view of this, for example, PTL 1 discloses an optical semiconductor device in which emission efficiency is improved by providing, directly below an active layer, a superlattice structure including GaInN, GaN, and the like having lower In composition than the active layer.

### CITATION LIST

### Patent Literature

PTL 1: Japanese Unexamined Patent Application Publication No. 2011-35433

### SUMMARY OF THE INVENTION

Thus, light-emitting devices including GaN-based materials have been desired to improve emission efficiency.

It is desirable to provide a light-emitting device that makes it possible to improve emission efficiency.

A light-emitting device according to one embodiment of the present disclosure includes: a substrate; a first quantum well layer including Alₓ₂Inₓ₁Ga₍₁₋ₓ₁₋ₓ₂₎N (0<x1<1, 0≤x2<1) and including a light-emitting region; a barrier layer provided between the substrate and the first quantum well layer; and a second quantum well layer including Al_{y2}In_{y1}Ga_{(1-y1-y2)}N (0<y1<1, 0≤y2<1) and having a thickness of less than 4.0 monolayers and provided between the substrate and the barrier layer, at a position 8 nm or more and less than 50 nm away from the first quantum well layer.

In the light-emitting device according to one embodiment of the present disclosure, between the substrate and the barrier layer, the second quantum well layer including Al_{y2}In_{y1}Ga_{(1-y1-y2)}N (0<y1<1, 0≤y2<1) and having a thickness of less than 4.0 monolayers is provided 8 nm or more and less than 50 nm away from the first quantum well layer provided on the barrier layer, including Alₓ₂Inₓ₁Ga₍₁₋ₓ₁₋ₓ₂₎N (0<x1<1, 0≤x2<1), and including one light-emitting layer. Thus, two-dimensional growth of the first quantum well layer is promoted, which reduces variations in In composition of the first quantum well layer and variations in film thickness of each layer, and improves steepness of In composition in a stacking direction.

In the light-emitting device according to one embodiment of the present disclosure, below the first quantum well layer including Alₓ₂Inₓ₁Ga₍₁₋ₓ₁₋ₓ₂₎N (0<x1<1, 0≤x2<1) and including the light-emitting region, the second quantum well layer including Al_{y2}In_{y1}Ga_{(1-y1-y2)}N (0<y1<1, 0≤y2<1) and having a thickness of less than 4.0 monolayers is provided, via the barrier layer, 8 nm or more and less than 50 nm away from the first quantum well layer. Thus, the two-dimensional growth of the first quantum well layer is promoted. This reduces variations in the In composition of the first quantum well layer and variations in the film thickness of each layer, and improves the steepness of the In composition in the stacking direction, making it possible to improve emission efficiency.

It is to be noted that the effects described here are not necessarily limitative and may be any of the effects described in the present disclosure.

### BRIEF DESCRIPTION OF DRAWINGS

FIG. 1 is a schematic cross-sectional diagram illustrating a configuration of a light-emitting device according to an embodiment of the present disclosure.

FIG. 2 is a diagram illustrating a bandgap of each layer of the light-emitting device illustrated in FIG. 1.

FIG. 3 is a diagram illustrating the relationship between thickness of a quantum well layer and emission intensity.

FIG. 4 is a diagram illustrating the relationship between In composition of the quantum well layer with respect to a quantum well light-emitting layer and emission intensity.

FIG. 5A is a schematic cross-sectional diagram explaining a manufacturing process of the light-emitting device illustrated in FIG. 1.

FIG. 5B is a schematic cross-sectional diagram illustrating a step subsequent to FIG. 5A.

FIG. 5C is a schematic cross-sectional diagram illustrating a step subsequent to FIG. 5B.

FIG. 6 is a diagram illustrating emission intensity of each form.

FIG. 7 is a schematic cross-sectional diagram illustrating a configuration of a light-emitting device according to Modification Example 1 of the present disclosure.

FIG. 8 is a diagram illustrating a bandgap of each layer of the light-emitting device illustrated in FIG. 7.

FIG. 9 is a schematic cross-sectional diagram illustrating a configuration of a light-emitting device according to Modification Example 2 of the present disclosure.

FIG. 10 is a diagram illustrating a bandgap of each layer of the light-emitting device illustrated in FIG. 9.

FIG. 11 is a schematic cross-sectional diagram illustrating a configuration of a light-emitting device according to Modification Example 3 of the present disclosure.

### MODES FOR CARRYING OUT THE INVENTION

In the following, description is given of embodiments of the present disclosure in detail with reference to the drawings. The following description is merely a specific example of the present disclosure, and the present disclosure should not be limited to the following embodiments. Moreover, the present disclosure is not limited to arrangements, dimensions, dimensional ratios, and the like of each component illustrated in the drawings. It is to be noted that the description is given in the following order.

1. Embodiment (an example in which a quantum well layer not involved in light emission is provided below a quantum well light-emitting layer)

### 1-1. Configuration of Light-Emitting Device

### 1-2. Method of Manufacturing Light-Emitting Device

### 1-3. Workings and Effects

2. Modification Example 1 (an example in which two quantum well light-emitting layers are stacked)
3. Modification Example 2 (an example in which two quantum well layers and two quantum well light-emitting layers are stacked)
4. Modification Example 3 (an example of a configuration as a semiconductor laser)

### 1. Embodiment

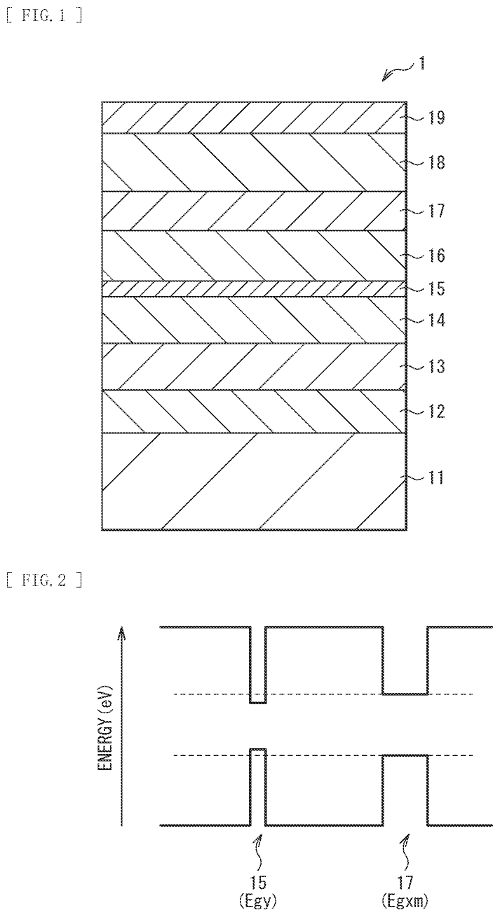

FIG. 1 schematically illustrates a cross-sectional configuration of a light-emitting device (light-emitting device 1) according to an embodiment of the present disclosure. The light-emitting device 1 is, for example, a light-emitting diode (LED) or the like that emits light having a wavelength of a visible region, in particular, 500 nm or more. The light-emitting device 1 of the present embodiment includes, on a substrate 11, a base layer 12, a n-AlGaInN layer 13, a n-GaInN layer 14, a quantum well layer 15 (second quantum well layer), a barrier layer 16, a quantum well light-emitting layer 17 (first quantum well layer), a p-AlGaInN layer 18, and a p⁺⁺-AlGaInN layer 19 stacked in this order. The quantum well layer 15 is provided at a position 8 nm or more and less than 50 nm away from the quantum well light-emitting layer 17, and has a thickness of less than 4.0 monolayers.

### (1-1. Configuration of Light-Emitting Device)

The light-emitting device 1 is formed using a gallium nitride (GaN)-based material. In the light-emitting device 1, as described above, the base layer 12, the n-AlGaInN layer 13, the n-GaInN layer 14, the quantum well layer 15, the barrier layer 16, the quantum well light-emitting layer 17, the p-AlGaInN layer 18, and the p⁺⁺-AlGaInN layer 19 are stacked in this order.

The substrate 11 is, for example, a gallium nitride (GaN) substrate, whose thickness is, for example, 300 μm to 500 μm. For example, a c-plane of the GaN substrate is used as the principal plane.

The base layer 12 is provided on the substrate 11 and includes, for example, n-type AlGaInN. The base layer 12 has a thickness of, for example, 10 nm to 1000 nm.

The n-AlGaInN layer 13 is provided on the base layer 12 and includes n-type AlGaInN. The n-GaInN layer 14 is provided on the n-AlGaInN layer 13 and includes n-type GaInN.

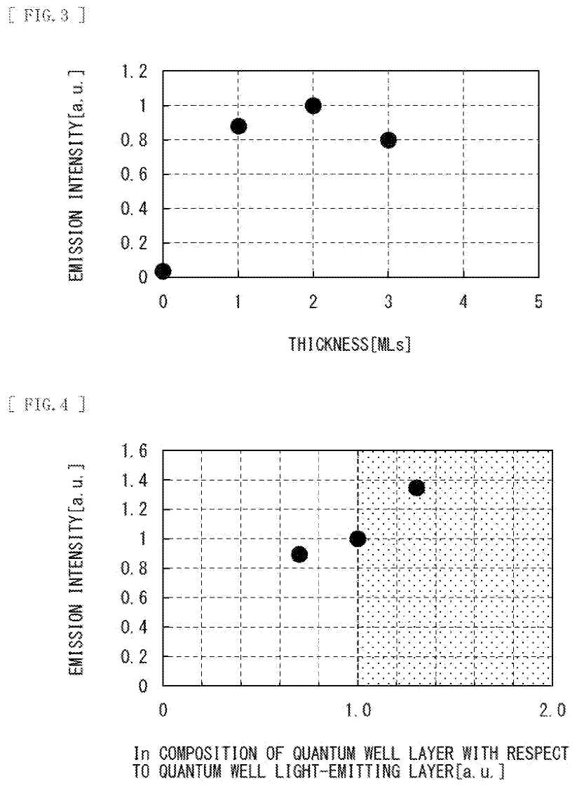

The quantum well layer 15 is provided on the n-GaInN layer 14. The quantum well layer 15 includes Al_{y2}In_{y1}Ga_{(1-y1-y2)}N (0<y1<1, 0≤y2<1). In a case where the quantum well layer 15 and the quantum well light-emitting layer 17 both include GaInN, indium (In) composition of the quantum well layer 15 preferably contains In equal to or more than that of the quantum well light-emitting layer 17 to be described later, and is, for example, 15% or more and 50% or less. In a case where the quantum well layer 15 and the quantum well light-emitting layer 17 include AlGaInN, bandgap energy (Egy) of the quantum well layer 15 is preferably equal to or less than bandgap energy (Egxm) of the quantum well light-emitting layer 17, as illustrated in FIG. 2. It is to be noted that the horizontal direction of FIG. 2 corresponds to a thickness of the light-emitting device 1 in a stacking direction.

The quantum well layer 15 does not contribute to light emission, and is preferably formed with a thickness of less than 4 monolayers (Mono Layers; MLs), more preferably 0.5 monolayers or more and 3.5 monolayers or less. Here, in a case of a Group III-V compound semiconductor, for example, monolayer (MLs) refers to an interatomic distance of Groups III-V-III, and corresponds to 0.26 nm in a case of a C-axis direction of hexagonal GaN. Further, the quantum well layer 15 is spaced apart at a position 8 nm or more and less than 50 nm from the quantum well light-emitting layer 17, as described above. Thus, it is assumed that the quantum well layer 15 is in an isolated quantum-well state in terms of a wave function and does not form a superlattice structure. It is to be noted that the position 8 nm or more and less than 50 nm away from the quantum well light-emitting layer 17 is a position from a surface on the substrate 11 side of a well provided on the most substrate 11 side of the quantum well light-emitting layer 17.

The barrier layer 16 is provided between the quantum well layer 15 and the quantum well light-emitting layer 17. The barrier layer 16 includes, for example, GaN, GaInN, or AlGaN, and may be a stacked film or a superlattice structure in which two or more layers of these are stacked. As described above, a distance between the quantum well layer 15 and the quantum well light-emitting layer 17 is preferably 8 nm or more and less than 50 nm. Therefore, for example, the barrier layer 16 preferably has a thickness of 8 nm or more and less than 50 nm. If the distance between the quantum well layer 15 and the quantum well light-emitting layer 17 is less than 8 nm, total strain accumulation of the quantum well layer 15 and the quantum well light-emitting layer 17 increases, which can result in propagation of crystal defects and deterioration of flatness. On the other hand, if the distance between the quantum well layer 15 and the quantum well light-emitting layer 17 is 50 nm or more, surface information of the quantum well layer 15 is lost. Thus, two-dimensional growth of the quantum well light-emitting layer 17 is not promoted. It is to be noted that, in a case where the barrier layer 16 has a stacked structure including two or more stacked layers and contains a superlattice structure in the stacked structure, a single layer with a thickness of 8 nm or more and less than 50 nm may be provided to sandwich the superlattice structure.

The quantum well light-emitting layer 17 is provided on the barrier layer 16. The quantum well light-emitting layer 17 includes Alₓ₂Inₓ₁Ga₍₁₋ₓ₁₋ₓ₂₎N (0<x1<1, 0≤x2<1) and has a light-emitting region in the layer. In a case where the quantum well layer 15 and the quantum well light-emitting layer 17 both include GaInN, indium (In) composition of the quantum well light-emitting layer 17 is preferably equal to or less than that of the quantum well layer 15, and is, for example, 15% or more and 50% or less. The quantum well light-emitting layer 17 preferably has a thickness of, for example, 2 nm or more and 4 nm or less.

The p-AlGaInN layer 18 is provided on the quantum well light-emitting layer 17 and includes p-type AlGaInN. The p⁺⁺-AlGaInN layer 19 is provided on the p-AlGaInN layer 18 and includes p-type AlGaInN doped with an acceptor heavily than the p-AlGaInN layer 18.

FIG. 3 illustrates the relationship between thickness of the quantum well layer 15 and emission intensity of the quantum well light-emitting layer 17. By providing the quantum well layer 15 of 1 MLs to 3 MLs, an emission intensity increased by an order of magnitude or more has been obtained, as compared with a case where the quantum well layer 15 is not provided (0 MLs). Thus, a remarkable improvement in emission efficiency has been confirmed. It is to be noted that the distance between the quantum well layer 15 and the quantum well light-emitting layer 17 (the thickness of the barrier layer 16) at this time was 15 nm. In a case where the distance was 5 nm, the emission intensity decreased to less than ⅔ of the emission intensity at each thickness of the quantum well layer 15 illustrated in FIG. 3.

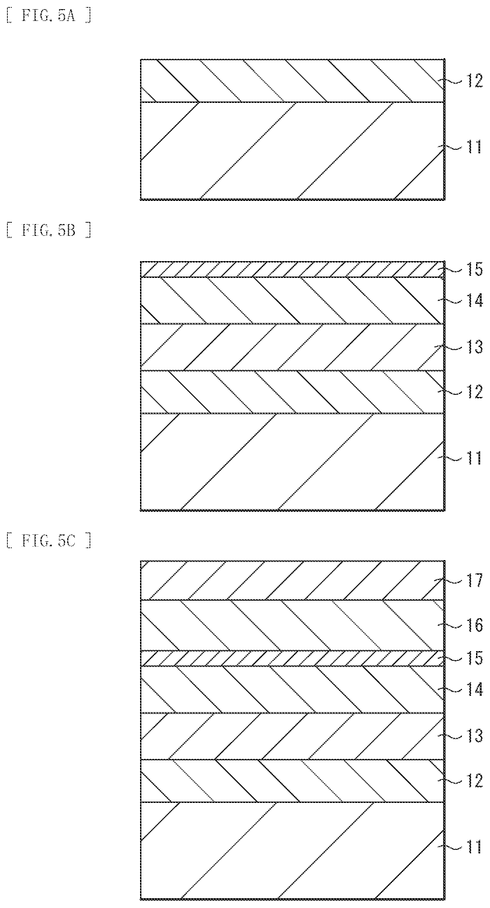

FIG. 4 illustrates the relationship between In composition of the quantum well layer 15 with respect to the quantum well light-emitting layer 17 and emission intensity of the quantum well light-emitting layer 17. Here, the thickness of the quantum well layer 15 was 2 MLs in all cases. As indicated by FIG. 4, with an increase in the In composition of the quantum well layer 15, the emission intensity of the quantum well light-emitting layer 17 increased. In particular, it is indicated that the In composition equal to or more than that of the quantum well light-emitting layer 17 is preferable.

### (1-2. Method of Manufacturing Light-Emitting Device)

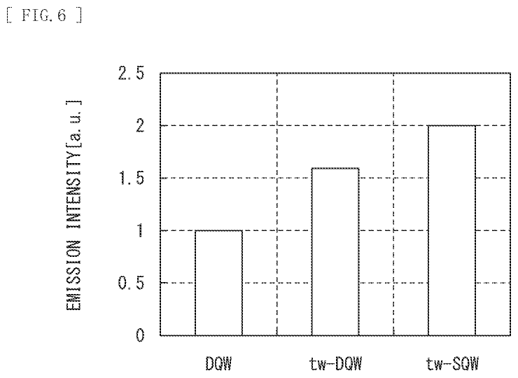

The light-emitting device 1 of the present embodiment is able be manufactured as follows, for example. FIGS. 5A to 5C illustrate the method of manufacturing the light-emitting device 1 in order of steps.

First, as illustrated in FIG. 5A, the base layer 12 is formed on the substrate 11. Specifically, on the substrate 11 including GaN, for example, a n-AlGaInN layer is grown at a temperature of 700° C. to 1200° C. Thus, the base layer 12 is formed on the substrate 11.

Next, as illustrated in FIG. 5B, the n-AlGaInN layer 13, the n-GaInN layer 14, and the quantum well layer 15 are formed in order on the base layer 12. The n-AlGaInN layer 13 is formed, for example, by growing n-type AlGaInN, doped with a donor such as Si, on the base layer 12 at a temperature of 700° C. to 1200° C. The n-GaInN layer 14 is formed, for example, by growing n-type GaInN, doped with a donor such as Si, on the n-AlGaInN layer 13 at a temperature of 700° C. to 900° C. The quantum well layer 15 is formed, for example, by growing Al_{y2}In_{y1}Ga_{(1-y1-y2)}N (0<y1<1, 0≤y2<1) on the n-GaInN layer 14 at a temperature of 600° C. to 900° C. at a thickness of 2 MLs, for example.

Next, as illustrated in FIG. 5C, the barrier layer 16 and the quantum well light-emitting layer 17 are formed in order on the quantum well layer 15. The barrier layer 16 is formed by growing GaN on the n-AlGaInN layer 13, for example, at a temperature of 600° C. to 900° C. The quantum well light-emitting layer 17 is formed, for example, by growing Alₓ₂Inₓ₁Ga₍₁₋ₓ₁₋ₓ₂₎N (0<x1<1, 0≤x2<1) on the barrier layer 16 at a temperature of 600° C. to 900° C. at a thickness of 3 nm, for example.

Finally, the p-AlGaInN layer 18 and the p⁺⁺-AlGaInN layer 19 are formed in order on the quantum well light-emitting layer 17. The p-AlGaInN layer 18 is formed, for example, by growing p-type AlGaInN, doped with an acceptor such as Mg, on the quantum well light-emitting layer 17 at a temperature of 600° C. to 1000° C. The p⁺⁺-AlGaInN layer 19 is formed, for example, by growing p-type AlGaInN, heavily doped with an acceptor such as Mg, on the p-AlGaInN layer 18 at a temperature of 600° C. to 1000° C. Thus, the light-emitting device 1 illustrated in FIG. 1 is completed.

### (1-3. Workings and Effects)

Light-emitting devices including gallium nitride (GaN)-based materials have been developed as light-emitting elements of a visible region, and one of applications thereof is a display including RGB light-emitting elements. Of the visible region, blue and green bands have already been put into practical use in LEDs and LDs including GaN-based materials. However, LEDs and LDs that emit light in the green band are desired to improve emission efficiency. GaInP-based materials are used in light-emitting devices that emit light in the red band. However, LEDs and LDs including GaInP-based materials have low emission efficiency particularly at high temperatures, and are desired to achieve further higher power and higher efficiency in laser display applications, for example.

In general, GaInN is used for an active layer in visible-region light-emitting elements including GaN-based materials. GaInN increases in emission wavelength with an increase in composition of In. The emission wavelength falls within, for example, the blue band at 16%, the green band at 23%, and the red band at 33%, though the emission wavelength changes depending on a thickness of the active layer. On the other hand, as the composition of In increases, emission recombination probability decreases and non-emission recombination probability increases. It is thus difficult to provide LEDs or LDs with favorable emission characteristics at a wavelength region longer than the blue band.

Examples of a factor that reduces the emission recombination probability include an increase in In composition variations and an increase in piezopolarization. Examples of a factor that increases the non-emission recombination probability include generation of crystal defects attributed to an increase in a degree of lattice mismatch between a GaN substrate or a GaN-template substrate and the GaInN active layer. In addition, in general, GaInN with high In composition tends to have a surface with a three-dimensional shape. Therefore, the light-emitting layer including GaInN and a barrier layer provided above the light-emitting layer are likely to decrease in flatness. This is likely to cause film thickness variations of each layer included in the light-emitting element and steepness of In composition in the stacking direction to deteriorate. This results in non-uniform emission wavelength and, in particular, reduces gain desired for lasing in a semiconductor laser.

Examples of a method of solving the above issue include the following two methods. The first method is to stack, directly below an active layer, a superlattice structure including GaInN, GaN, and the like having lower In composition than the active layer. The first method aims to reduce the amount of strain applied to the active layer with respect to the generation of crystal defects attributed to the increase of the degree of lattice mismatch. The second method is to stack AlGaN as a strain compensating layer for GaInN, above and below the GaInN active layer, for example. The above methods are expected to provide certain effects in reduction of piezopolarization and suppression of crystal defects resulting from reduction of the amount of strain. It is, however, difficult to sufficiently improve variations in the In composition, film thickness variations due to deterioration of flatness, and steepness of the In composition in the stacking direction. A further improvement in emission efficiency is thus desired.

In view of this, in the light-emitting device 1 of the present embodiment, the quantum well layer 15 including Al_{y2}In_{y1}Ga_{(1-y1-y2)}N (0<y1<1, 0≤y2<1) and having a thickness of less than 4.0 monolayers is provided between the substrate 11 and the quantum well light-emitting layer 17 including Alₓ₂Inₓ₁Ga₍₁₋ₓ₁₋ₓ₂₎N (0<x1<1, 0≤x2<1), at a position 8 nm or more and less than 50 nm away from the quantum well light-emitting layer 17.

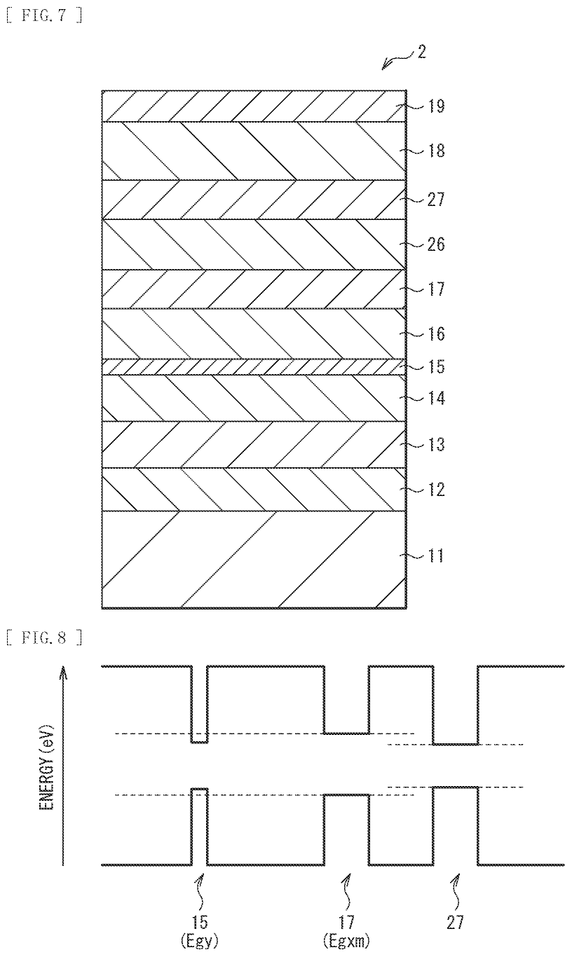

FIG. 6 illustrates emission intensity of the following: a light-emitting device (DQW) having a Double Quantum Well structure in which two quantum well light-emitting layers are stacked without providing the quantum well layer 15; the light-emitting device 1 (thin well-Single Quantum Well; tw-SQW) of the present embodiment; and a light-emitting device 2 (thin well-Double Quantum Well; tw-DQW) of Modification Example 1 to be described later. It is to be noted that “tw” corresponds to the quantum well layer 15 described above. Comparison of emission intensity indicates that providing the quantum well layer 15 greatly increases the emission intensity. Table 1 summarizes emission intensity, internal quantum efficiency, defects, interface steepness, and flatness of quantum well light-emitting layers in a light-emitting device (SQW) having a Single Quantum Well structure with one quantum well light-emitting layer, the DQW, the tw-SQW, and the tw-DQW. In Table 1, each item is evaluated in four levels: A, B, C, and D. The emission intensity and the internal quantum efficiency were both evaluated as A, B, C, and D in order from higher values. The defects were evaluated as A, B, C, and D in order from lower defect density. The interface steepness was evaluated as A, B, C, and D in order from larger amplitude heights of satellite peaks of the DQW obtained by XRD-evaluation. The flatness was evaluated as A, B, C, and D in order from higher intensity of reflected light applied onto a crystalline surface when the quantum well active layer was grown. In other words, A represents the best evaluation for all items.

TABLE 1

| | Emission | | | |
|---|---|---|---|---|
| | intensity and | | | |
| | internal | | | |
| | quantum | Ring-shaped | Interface | Flatness |
| | efficiency | defects | steepness | (in-situ) |
| SQW | D | A | B | C |
| tw-SQW | A | A | A | A |
| DQW | C | B | B | C |
| tw-DQW | B | B | A | A |

According to these results, providing the quantum well layer 15 having the above configuration below the quantum well light-emitting layer 17, as in the present embodiment, promotes the two-dimensional growth of the quantum well light-emitting layer. This reduces variations in the In composition of the quantum well light-emitting layer 17 and variations in the film thickness of the quantum well light-emitting layer 17 and layers formed further above. In addition, it is possible to improve steepness of the In composition in the stacking direction.

As described above, in the light-emitting device 1 of the present embodiment and the light-emitting device 2 to be described later, the quantum well layer 15 including Al_{y2}In_{y1}Ga_{(1-y1-y2)}N (0<y1<1, 0≤y2<1) and having a thickness of less than 4.0 monolayers is provided below the quantum well light-emitting layer 17 including Alₓ₂Inₓ₁Ga₍₁₋ₓ₁₋ₓ₂₎N (0<x1<1, 0≤x2<1) via the barrier layer 16, at a position 8 nm or more and less than 50 nm away from the quantum well light-emitting layer 17. This reduces variations in the In composition of the quantum well light-emitting layer 17 and variations in the film thickness of the layers formed above including the quantum well light-emitting layer 17, and improves steepness of the In composition in the stacking direction, making it possible to improve emission efficiency.

In particular, the present embodiment provides greater effects in a light-emitting device with a quantum well light-emitting layer having an emission wavelength longer than the blue band. For example, it is possible to significantly improve emission efficiency in a light-emitting device (a light-emitting diode (LD), a semiconductor laser (LED) to be described later, and the like) that emits light in the green band or the red band.

Next, modification examples (Modification Examples 1 to 3) of the present disclosure are described. Hereinafter, components similar to those of the embodiment described above are denoted by the same reference numerals, and description thereof is omitted as appropriate.

### 2. Modification Example 1

FIG. 7 schematically illustrates a cross-sectional configuration of the light-emitting device (light-emitting device 2) according to the modification example (Modification Example 1) of the present disclosure. The light-emitting device 2 is, for example, a light-emitting diode or the like that emits light having a wavelength of a visible region, in particular, 500 nm or more. In the light-emitting device 2, as in the above embodiment, the quantum well layer 15 having a thickness of less than 4.0 monolayers is provided below the quantum well light-emitting layer 17 via the barrier layer 16, at a position 8 nm or more and less than 50 nm away. The present modification example differs from the above embodiment in that a quantum well light-emitting layer 27 is further provided on the quantum well light-emitting layer 17 via a barrier layer 26.

The barrier layer 26 is provided on the quantum well light-emitting layer 17. Like the barrier layer 16, the barrier layer 26 includes GaN, GaInN, or AlGaN, for example, and may be a structure or superlattice structure in which two or more layers of these are stacked. The barrier layer 26 may have a thickness of, for example, 2 nm or more and 20 nm or less.

The quantum well light-emitting layer 27 is provided on the barrier layer 26. Like the quantum well light-emitting layer 17, the quantum well light-emitting layer 27 includes Alₓ₂Inₓ₁Ga₍₁₋ₓ₁₋ₓ₂₎N (0<x1<1, 0≤x2<1). In a case where the quantum well layer 15 and the quantum well light-emitting layer 27 both include GaInN, indium (In) composition of the quantum well light-emitting layer 27 is preferably equal to or less than that of the quantum well layer 15, and is, for example, 15% or more and 50% or less. The quantum well light-emitting layer 27 preferably has a thickness of, for example, 2 nm or more and 4 nm or less.

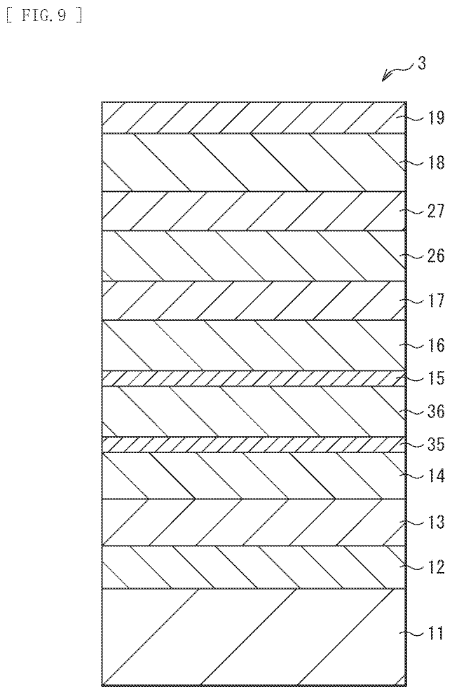

FIG. 8 illustrates bandgaps of the quantum well layer 15, the quantum well light-emitting layer 17, and the quantum well light-emitting layer 27. As the magnitude relationship of bandgap energy between the quantum well layer 15, the quantum well light-emitting layer 17, and the quantum well light-emitting layer 27 in the present modification example, the bandgap energy (Egy) of the quantum well layer 15 is preferably equal to or less than the bandgap energy (Egxm) of the layer having a larger bandgap energy out of the quantum well light-emitting layer 17 and the quantum well light-emitting layer 27. For example, in a case where the bandgap energy of the quantum well light-emitting layer 27 is greater than the bandgap energy of the quantum well light-emitting layer 17, unlike in FIG. 8, the bandgap energy (Egy) of the quantum well layer 15 is preferably equal to or less than the bandgap energy of the quantum well light-emitting layer 27.

Thus, even in the light-emitting device 2 including the two quantum well light-emitting layers 17 and 27, providing the quantum well layer 15 including Al_{y2}In_{y1}Ga_{(1-y1-y2)}N (0<y1<1, 0≤y2<1) and having a thickness of less than 4.0 monolayers between the quantum well light-emitting layer 17 disposed on the lower layer side and the substrate 11, at a position 8 nm or more and less than 50 nm away from the quantum well light-emitting layer 17, makes it possible to improve emission efficiency, as in the above embodiment.

### 3. Modification Example 2

FIG. 9 schematically illustrates a cross-sectional configuration of a light-emitting device (light-emitting device 3) according to a modification example (Modification Example 2) of the present disclosure. The light-emitting device 3 is, for example, a light-emitting diode or the like that emits light having a wavelength of a visible region, in particular, 500 nm or more. The light-emitting device 3 differs from Modification Example 1 in that two quantum well layer 15 and 35 are provided below the quantum well light-emitting layer 17 via respective barrier layers 16 and 36. Specifically, the light-emitting device 3 of the present modification example has a configuration in which, on the substrate 11, the base layer 12, the n-AlGaInN layer 13, the n-GaInN layer 14, the quantum well layer 35 (third quantum well layer), the barrier layer 36, the quantum well layer 15, the barrier layer 16, the quantum well light-emitting layer 17, the barrier layer 26, the quantum well light-emitting layer 27, the p-AlGaInN layer 18, and the p⁺⁺-AlGaInN layer 19 are stacked in this order.

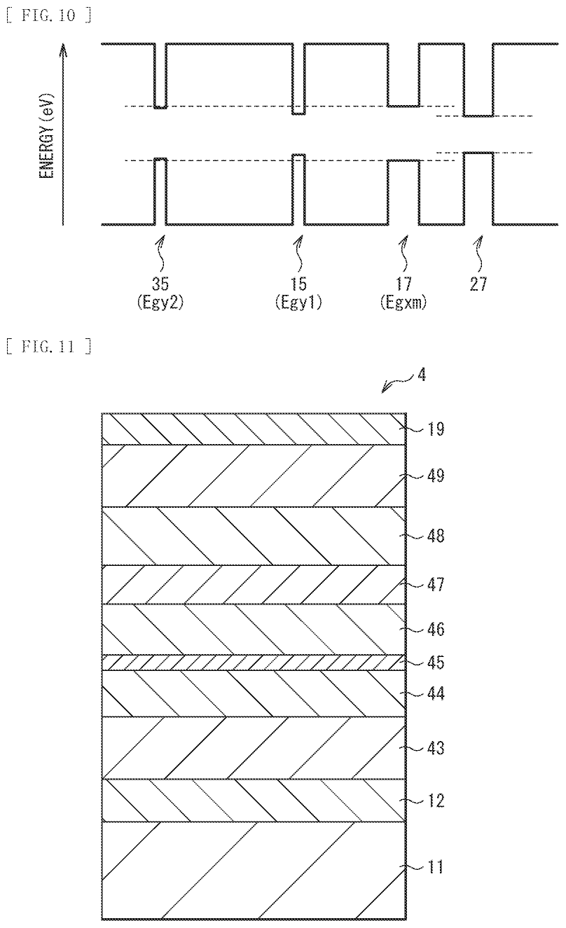

The quantum well layer 35 is provided on the n-GaInN layer. Like the quantum well layer 15, the quantum well layer 35 includes Al_{y2}In_{y1}Ga_{(1-y1-y2)}N (0<y1<1, 0≤y2<1). In a case where the quantum well layers 15 and 35 and the quantum well light-emitting layers 17 and 27 both include GaInN, indium (In) composition of the quantum well layer 35 is preferably equal to or more than those of the quantum well light-emitting layers 17 and 27, and is, for example, 15% or more and 50% or less. In a case where the quantum well layers 15 and 35 and the quantum well light-emitting layers 17 and 27 include AlGaInN, bandgap energy (Egy2) of the quantum well layer 35 is, like the bandgap energy (Egy1) of the quantum well layer 15, preferably equal to or less than the bandgap energy (Egxm) of the quantum well light-emitting layer having the larger bandgap energy out of the quantum well light-emitting layers 17 and 27 (in FIG. 10, the quantum well light-emitting layer 17).

The quantum well layer 35 does not contribute to light emission, and is preferably formed with a thickness of less than 4 monolayers (MLs), more preferably 0.5 monolayers or more and 3.5 monolayers or less, like the quantum well layer 15. The quantum well layer 35 and the quantum well layer 15 are preferably spaced apart by a distance of, for example, 8 nm or more and less than 50 nm. As in the above embodiment and Modification Example 1, this reduces variations in the In composition of the quantum well light-emitting layer 17 and the quantum well light-emitting layer 27 and variations in the film thickness of the layers formed above including the quantum well light-emitting layer 17 and the quantum well light-emitting layer 27, and improves steepness of the In composition in the stacking direction, making it possible to improve emission efficiency.

The barrier layer 36 is provided between the quantum well layer 35 and the quantum well layer 15. Like the barrier layer 16, the barrier layer 36 includes GaN, GaInN, or AlGaN, for example, and may be a structure or superlattice structure in which two or more layers of these are stacked. Like the barrier layer 16, the barrier layer 36 preferably has a thickness of 8 nm or more and less than 50 nm. It is to be noted that, in a case where the barrier layer 36 has a stacked structure including two or more stacked layers and contains a superlattice structure in the stacked structure, a single layer with a thickness of 8 nm or more and less than 50 nm may be provided to sandwich the superlattice structure.

Thus, even in the light-emitting device 3 including the two quantum well layer 15 and 35 below the quantum well light-emitting layer 17, providing the quantum well layer 15 including Al_{y2}In_{y1}Ga_{(1-y1-y2)}N (0<y1<1, 0≤y2<1) and having a thickness of less than 4.0 monolayers between the quantum well light-emitting layer 17 disposed on the lower layer side and the substrate 11, at a position 8 nm or more and less than 50 nm away from the quantum well light-emitting layer 17, and providing the quantum well layer 35 below the quantum well layer 15 at a position 8 nm or more and less than 50 nm away from the quantum well layer 15 makes it possible to improve emission efficiency, as in the above embodiment.

### 4. Modification Example 3

FIG. 11 schematically illustrates an exemplary cross-sectional configuration of a light-emitting device (light-emitting device 4) according to a modification example (Modification Example 3) of the present disclosure. The light-emitting device 4 is an example of a semiconductor laser that emits light having a wavelength of, for example, a visible region, particularly 500 nm or more. In the light-emitting device 4 of the present modification example, as in the above embodiment, a quantum well layer 45 having a thickness of less than 4.0 monolayers is provided below a quantum well light-emitting layer 47 via a barrier layer 46, at a position 8 nm or more and less than 50 nm away. The light-emitting device 4 has a configuration in which, on the substrate 11, the base layer 12, a lower cladding layer 43, a guide layer 44, the quantum well layer 45, the barrier layer 46, the quantum well light-emitting layer 47, a guide layer 48, an upper cladding layer 49, and the p⁺⁺-AlGaInN layer 19 are stacked in this order.

The lower cladding layer 43 is provided on the base layer 12 and includes n-type AlGaInN. The guide layer 44 is provided on the lower cladding layer 43 and includes undoped or n-type GaInN.

The quantum well layer 45 is provided on the guide layer 44. Like the above quantum well layer 15, the quantum well layer 45 includes Al_{y2}In_{y1}Ga_{(1-y1-y2)}N (0<y1<1, 0≤y2<1). In a case where the quantum well layer 45 and the quantum well light-emitting layer 47 both include GaInN, indium (In) composition of the quantum well layer 45 is preferably equal to or more than that of the quantum well light-emitting layer 47 to be described later, and is, for example, 15% or more and 50% or less. In a case where the quantum well layer 45 and the quantum well light-emitting layer 47 include AlGaInN, bandgap energy (Egy) of the quantum well layer 45 is preferably equal to or less than bandgap energy of the quantum well light-emitting layer 47.

The quantum well layer 45 does not contribute to light emission, and is preferably formed with a thickness of less than 4 monolayers (MLs). As described above, the quantum well layer 45 is spaced apart by a distance of 8 nm or more and less than 50 nm from the quantum well light-emitting layer 47. Thus, it is assumed that the quantum well layer 45 is in an isolated quantum-well state in terms of the wave function and does not form a superlattice structure.

The barrier layer 46 is provided between the quantum well layer 45 and the quantum well light-emitting layer 47. Like the above barrier layer 16, the barrier layer 46 includes GaN, GaInN, or AlGaN, for example, and may be a structure or superlattice structure in which two or more layers of these are stacked. As described above, the distance between the quantum well layer 45 and the quantum well light-emitting layer 47 is preferably 8 nm or more and less than 50 nm, and therefore, the barrier layer 46 preferably has a thickness of 8 nm or more and less than 50 nm, for example. If the distance between the quantum well layer 45 and the quantum well light-emitting layer 47 is less than 8 nm, the total strain accumulation of the quantum well layer 45 and the quantum well light-emitting layer 47 increases, which can result in propagation of crystal defects and deterioration of flatness. On the other hand, if the distance between the quantum well layer 45 and the quantum well light-emitting layer 47 is 50 nm or more, the surface information of the quantum well layer 45 is lost. Thus, the two-dimensional growth of the quantum well light-emitting layer 47 is not promoted. It is to be noted that, in a case where the barrier layer 46 has a stacked structure including two or more stacked layers and contains a superlattice structure in the stacked structure, a single layer with a thickness of 8 nm or more and less than 50 nm may be provided to sandwich the superlattice structure.

The quantum well light-emitting layer 47 is provided on the barrier layer 46. Like the above quantum well light-emitting layer 17, the quantum well light-emitting layer 47 includes Alₓ₂Inₓ₁Ga₍₁₋ₓ₁₋ₓ₂₎N (0<x1<1, 0≤x2<1). In a case where the quantum well layer 45 and the quantum well light-emitting layer 47 both include GaInN, indium (In) composition of the quantum well light-emitting layer 47 is preferably equal to or less than that of the quantum well layer 45, and is, for example, 15% or more and 50% or less. The quantum well light-emitting layer 47 preferably has a thickness of, for example, 2 nm or more and 4 nm or less.

The guide layer 48 is provided on the quantum well light-emitting layer 47 and includes undoped or p-type GaInN. The upper cladding layer 49 is provided on the guide layer 48 and includes p-type AlGaInN.

As described above, even in the semiconductor laser, providing the quantum well layer 45 including Al_{y2}In_{y1}Ga_{(1-y1-y2)}N (0<y1<1, 0≤y2<1) and having a thickness of less than 4.0 monolayers below the quantum well light-emitting layer 47, at a position 8 nm or more and less than 50 nm away from the quantum well light-emitting layer 47, makes it possible to improve emission efficiency, as in the above embodiment.

Although the present disclosure has been described above with reference to the embodiment and Modification Examples 1 to 3, the present disclosure is not limited to the above embodiment and may be modified in a variety of ways. For example, the components, arrangements, numbers, and the like of the light-emitting device 1 exemplified in the above embodiment are merely examples. All the components may not necessarily be provided, and other components may be further provided.

Furthermore, although the above embodiment, etc. have described an example of using a gallium nitride (GaN) substrate as the substrate 11, for example, any of a sapphire substrate, a silicon (Si) substrate, an aluminum nitride (AlN) substrate, and a zinc oxide (ZnO) substrate may be used as the substrate 11.

It is to be noted that the effects described in the present specification are merely exemplary and not limitative, and may have other effects.

It is to be noted that the present disclosure may have the following configurations.

(1)
A light-emitting device including:
a substrate;
a first quantum well layer including Alₓ₂Inₓ₁Ga₍₁₋ₓ₁₋ₓ₂₎N (0<x1<1, 0≤x2<1) and including a light-emitting region;

a barrier layer provided between the substrate and the first quantum well layer; and

a second quantum well layer including Al_{y2}In_{y1}Ga_{(1-y1-y2)}N (0<y1<1, 0≤y2<1) and having a thickness of less than 4.0 monolayers and provided between the substrate and the barrier layer, at a position 8 nm or more and less than 50 nm away from the first quantum well layer.

(2)
The light-emitting device according to (1), in which
the first quantum well layer is a single quantum well including one quantum well layer, and
bandgap energy (Egy) of the second quantum well layer is equal to or less than bandgap energy (Egxm) of the quantum well layer.
   (3)
The light-emitting device according to (1), in which
the first quantum well layer is a multiple quantum well including a plurality of quantum well layers, and
bandgap energy (Egy) of the second quantum well layer is equal to or less than bandgap energy (Egxm) of the quantum well layer having the largest bandgap energy of the plurality of quantum well layers.
   (4)
The light-emitting device according to any one of (1) to (3), in which the thickness of the second quantum well layer is 0.5 monolayers or more and 3.5 monolayers or less.
   (5)
The light-emitting device according to any one of (1) to (4), in which an emission wavelength of the first quantum well layer is 500 nm or more.
   (6)
The light-emitting device according to any one of (1) to (5), in which the second quantum well layer does not form a superlattice.
   (7)
The light-emitting device according to any one of (1) to (6), further including a third quantum well layer including Al_{y2}In_{y1}Ga_{(1-y1-y2)}N (0<y1<1, 0≤y2<1) and having a thickness of less than 4.0 monolayers between the substrate and the second quantum well layer.
   (8)
The light-emitting device according to any one of (1) to (7), in which the substrate includes a gallium nitride (GaN) substrate.
   (9)
The light-emitting device according to any one of (1) to (8), in which the substrate includes any of a sapphire substrate, a silicon (Si) substrate, an aluminum nitride (AlN) substrate, and a zinc oxide (ZnO) substrate.

This application claims the benefit of Japanese Priority Patent Application No. 2018-153056 filed with the Japan Patent Office on Aug. 16, 2018, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light-emitting device comprising:
a substrate;
a first quantum well layer including Alₓ₂Inₓ₁Ga₍₁₋ₓ₁₋ₓ₂₎N (0<x1<1, 0≤x2<1) and including a light-emitting region;
a barrier layer provided between the substrate and the first quantum well layer; and
a second quantum well layer including Al_{y2}In_{y1}Ga_{(1-y1-y2)}N (0<y1<1, 0≤y2<1) and having a thickness of less than 4.0 monolayers and provided between the substrate and the barrier layer, at a position 8 nm or more and less than 50 nm away from the first quantum well layer.

2. The light-emitting device according to claim 1, wherein
the first quantum well layer is a single quantum well including one quantum well layer, and
bandgap energy (Egy) of the second quantum well layer is equal to or less than bandgap energy (Egxm) of the quantum well layer.

3. The light-emitting device according to claim 1, wherein
the first quantum well layer is a multiple quantum well including a plurality of quantum well layers, and
bandgap energy (Egy) of the second quantum well layer is equal to or less than bandgap energy (Egxm) of the quantum well layer having the largest bandgap energy of the plurality of quantum well layers.

4. The light-emitting device according to claim 1, wherein the thickness of the second quantum well layer is 0.5 monolayers or more and 3.5 monolayers or less.

5. The light-emitting device according to claim 1, wherein an emission wavelength of the first quantum well layer is 500 nm or more.

6. The light-emitting device according to claim 1, wherein the second quantum well layer does not form a superlattice.

7. The light-emitting device according to claim 1, further comprising a third quantum well layer including Al_{y2}In_{y1}Ga_{(1-y1-y2)}N (0<y1<1, 0≤y2<1) and having a thickness of less than 4.0 monolayers between the substrate and the second quantum well layer.

8. The light-emitting device according to claim 1, wherein the substrate comprises a gallium nitride (GaN) substrate.

9. The light-emitting device according to claim 1, wherein the substrate comprises any of a sapphire substrate, a silicon (Si) substrate, an aluminum nitride (AlN) substrate, and a zinc oxide (ZnO) substrate.
